(19) United States
(12) Patent Application Publication
(10) Pub. No.: US 2008/0284423 A1
(43) Pub. Date: Nov. 20, 2008

(54) Detecting device for a motor of a ceiling fan

(75) Inventor: Tang Yung Yu, Taichung (TW)

Correspondence Address: BRUCE H. TROXELL, SUITE 1404, 5205 LEESBURG PIKE, FALLS CHURCH, VA, 22041, US

(73) Assignee: AIR COOL INDUSTRIAL CO., LTD.

(21) Appl. No.: 11/802,097

(22) Filed: May 18, 2007

(51) Int. Cl. G01R 33/07; H02K 11/00

(52) U.S. Cl. 324/244; 310/68 R

(57) ABSTRACT

The invention relates to a detecting device for a motor of a ceiling fan. The motor includes a stator, a rotor, a detecting device and a circuit board. The rotor is pivotally installed around a motor shaft and the detecting device is fixed on one surface of silica steel plates of the stator. The rotor has induction magnets, which respectively have their one end to be induced with the detecting device extended with a preset length able to cover at least a detectable range of the detecting device, so as to form a reliable detecting zone between the induction magnets and the detecting device.

### BACKGROUND OF THE INVENTION

1. Field of the Invention

This invention relates to a motor of a ceiling fan, particularly to one having its induction magnets respectively extended with a preset length to form an extra reliable detecting zone for a detecting device to induce without any error, keeping a rotor whirling without shaking.

2. Description of the Prior Art

As shown in FIG. 1, a conventional motor 10 of a ceiling fan is composed of a stator 11, a rotor 12, a detecting device 13 and a circuit board 14. The stator 11 is provided with a motor shaft 111 and a preset number of silica steel plates 112 that are laminated and installed around the motor shaft 111. A plurality of magnet coils 1121 are respectively wound around many sections of the silica steel plates 112 The rotor 12 is pivotally fixed around the motor shaft 111 of the stator 11, provided with an upper shell 121, a lower shell 122, an intermediate shell 123 and a preset number of induction magnets 124. The detecting device 13 is commonly fixed on an upper surface of the silica steel plates 112, connected with the circuit board 14 so as to transmit messages of the changes of the magnetic field detecting from the induction magnets 124 to the circuit board 14, which can then control the induced magnetic field generated by the magnet coils 1121 to keep the rotor 12 whirling steadily in a same direction.

However, as shown in FIGS. 2 and 3, a detectable range (S) to be detected by the detecting device 13 should be leveled as high as a top surface 1241 of each of the induction magnets 124 because the detecting device 13 is deadly fixed on the top surface of the silica steel plates 112. If one of the silica steel plates 112 should be positioned bias to the shaft 111 while assembling, the stator 11 might be positioned obliquely. Moreover, when the induction magnets 124 are rotated together with the rotor 12, they are not to be detected by one side of the detecting device 13 located higher than the top surface 1241 of the induction magnets 124, keeping the detecting device 13 intermittently detecting the change of the magnetic field of the induction magnets 124 as to have a unsteady detection. So, the detecting device 13 is unable to precisely transmit messages of the changes of the magnetic field detected from the induction magnets 124 to the circuit board 14, so that the rotor 12 is to have an unsteady rotation to make itself shaking at the same time.

### SUMMARY OF THE INVENTION

The objective of this invention is to offer a detecting device for a motor of a ceiling fan.

The main characteristics of the motor are a stator, a rotor, a detecting device and a circuit board. The rotor is pivotally installed around a motor shaft and the detecting device is fixed on one surface of silica steel plates. The rotor has induction magnets, which respectively have their one end to be induced with the detecting device extended with a preset length able to cover at least a detectable range of the detecting device, so as to form a reliable detecting zone between the induction magnets and the detecting device. Even if one of the silica steel plates should be assembled bias to keep the stator positioned obliquely, the induction magnets might still be able to induce completely with the detecting device because of the reliable detecting zone, enabling the detecting device to induce with the induction magnets completely without any error with the rotor steadily whirling in a same direction without shaking.

### BRIEF DESCRIPTION OF DRAWINGS

This invention is better understood by referring to the accompanying drawings, wherein:

FIG. 1 is a perspective view of a conventional motor of a ceiling fan;

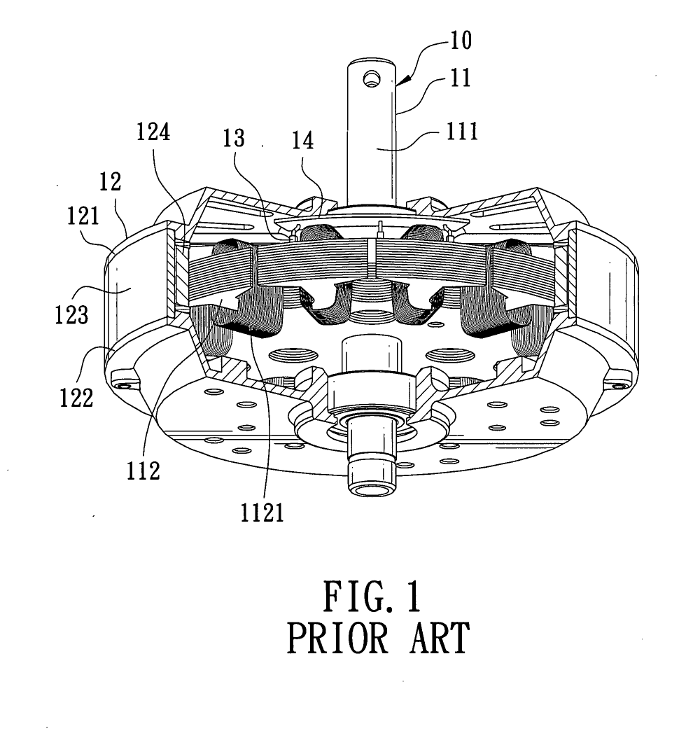

FIG. 2 is a cross-sectional view of the conventional motor of a ceiling fan, showing it being working;

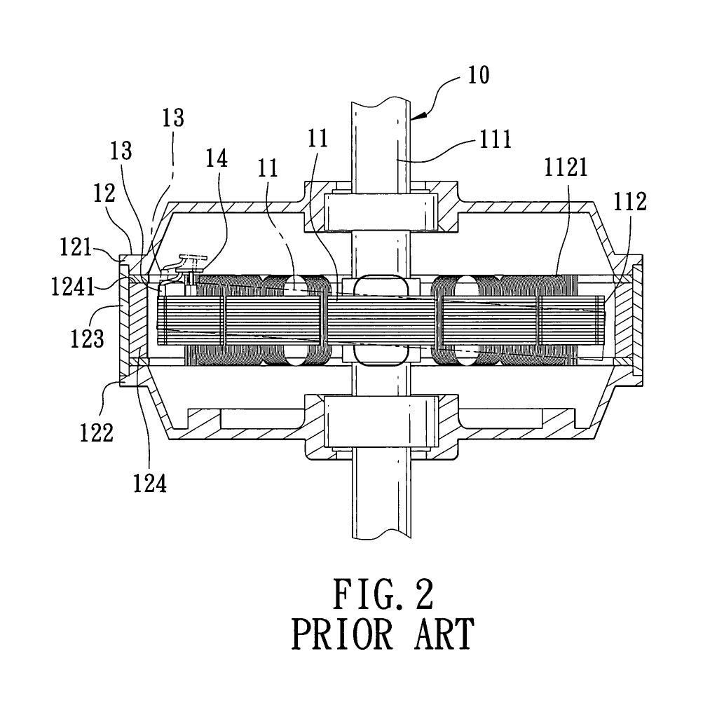

FIG. 3 is a magnified partial cross-sectional view of the conventional motor of a ceiling fan, showing it being working;

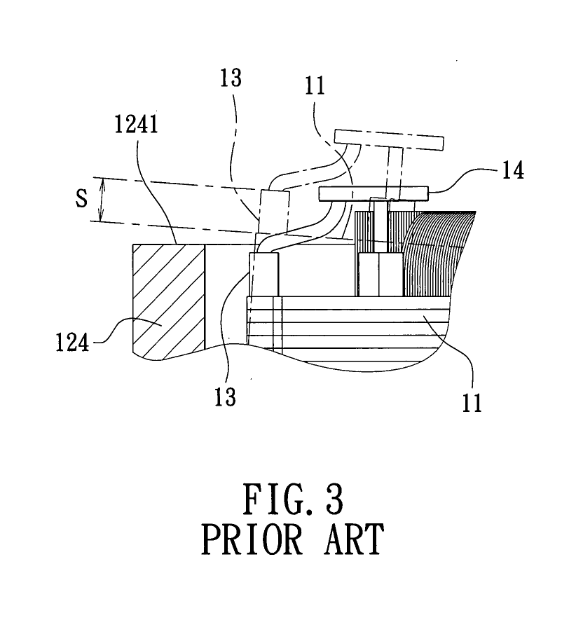

FIG. 4 is a perspective view of a first preferred embodiment of a detecting device for a motor of a ceiling fan in the present invention;

FIG. 5 is a partial exploded perspective view of the first preferred embodiment of a detecting device for a motor of a ceiling fan in the present invention;

FIG. 6 is a cross-sectional view of the first preferred embodiment of a detecting device for a motor of a ceiling fan in the present invention;

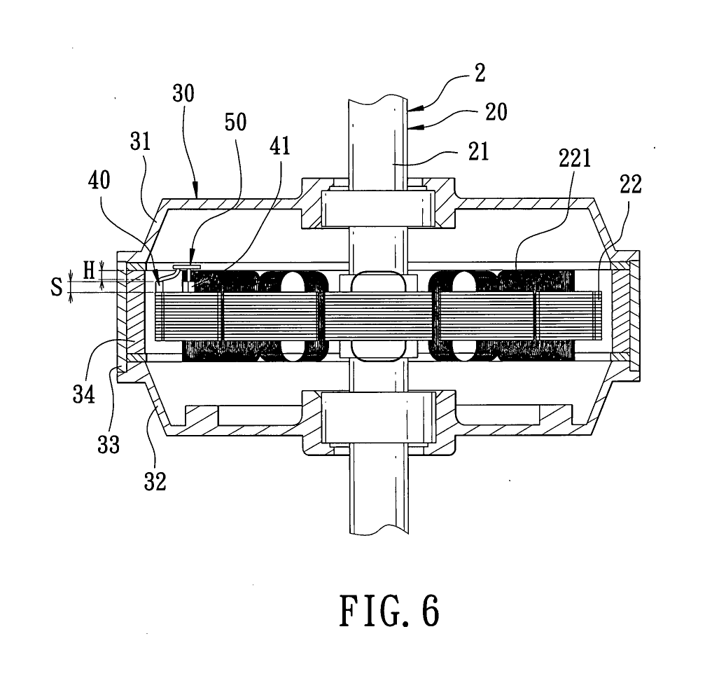

FIG. 7 is a cross-sectional view of the first preferred embodiment of a detecting device for a motor of a ceiling fan in the present invention, showing it being working;

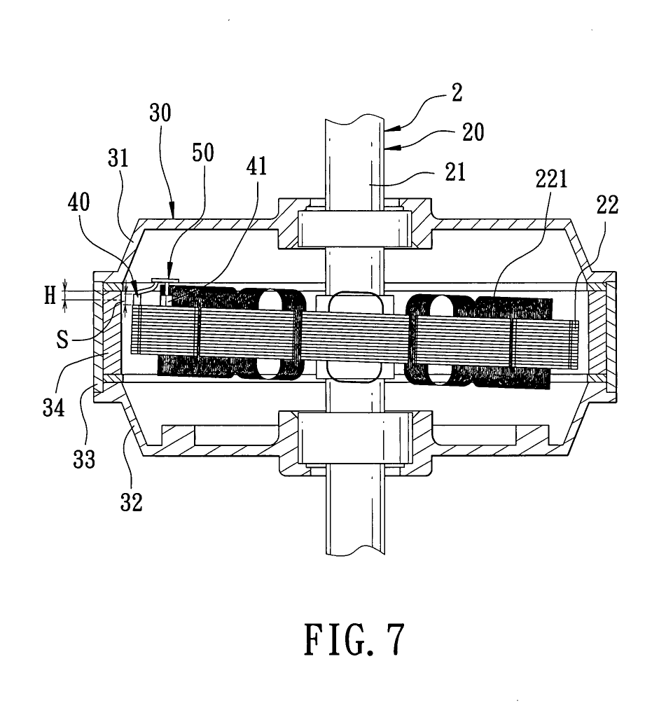

FIG. 8 is a partial cross-sectional view of the first preferred embodiment of a detecting device for a motor of a ceiling fan in the present invention, showing it being working;

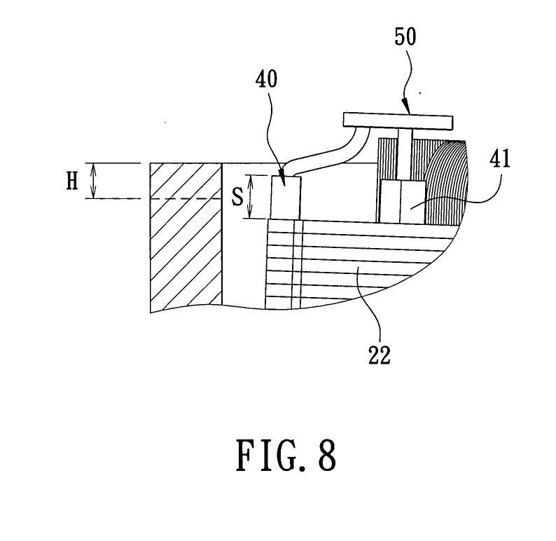

FIG. 9 is a cross-sectional view of a second preferred embodiment of a detecting device for a motor of a ceiling fan in the present invention, showing it being working;

FIG. 10 is a cross-sectional view of a third preferred embodiment of a detecting device for a motor of a ceiling fan in the present invention, showing it being working; and

FIG. 11 is a cross-sectional view of a fourth preferred embodiment of a detecting device for a motor of a ceiling fan in the present invention, showing it being working.

### DETAILED DESCRIPTION OF THE PREFERRED EMBODIMENT

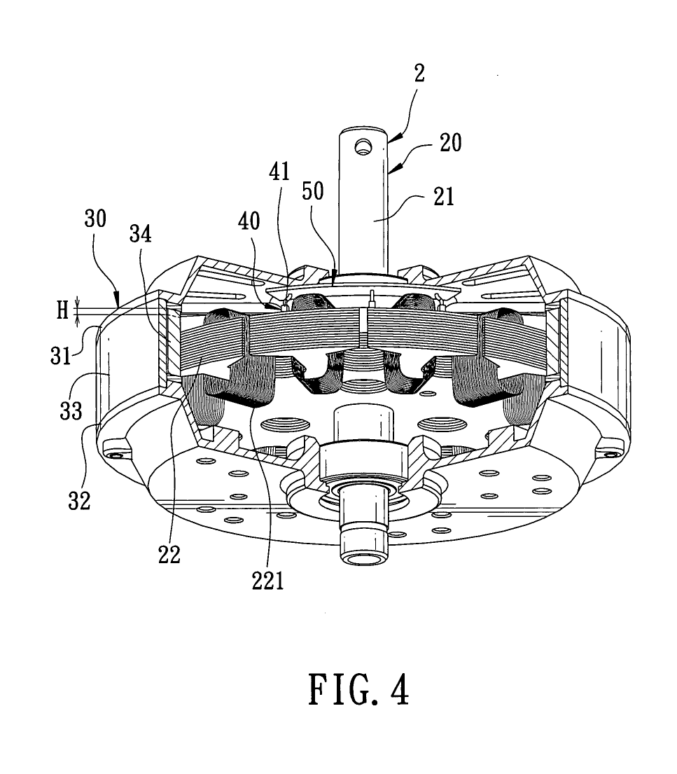

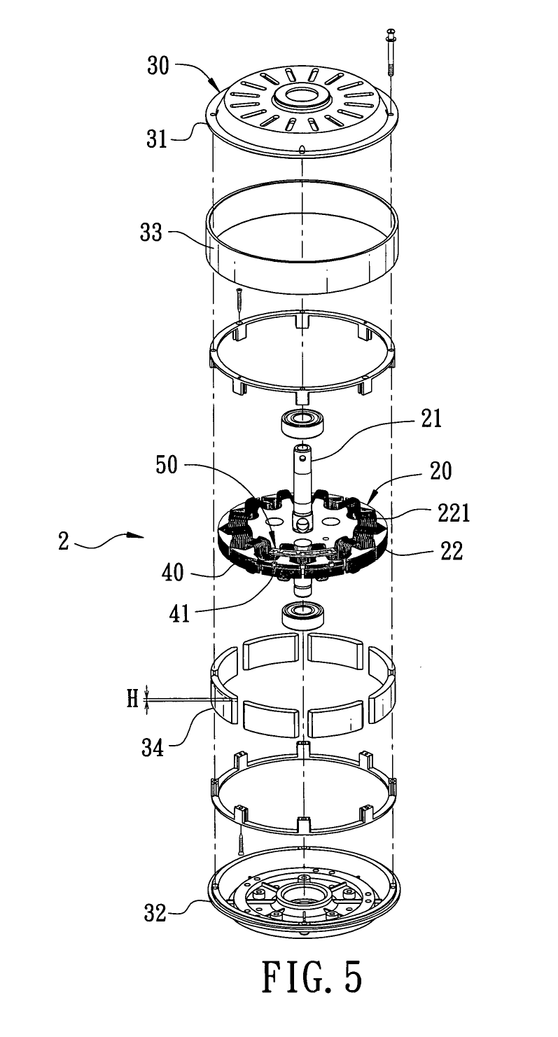

FIGS. 4 and 5 show a first preferred embodiment of a detecting device for a motor 2 of a ceiling fan in the present invention. The motor 2 is composed of a stator 20, a rotor 30, a detecting device 40 and a circuit board 50.

The stator 20 is provided with a motor shaft 21, and a preset number of silica steel plates 22 that are laminated and installed around the circumference of the motor shaft 21, spaced apart with equidistance. A plurality of magnet coils 221 are respectively wound around many sections of the silica steel plates 22.

The rotor 30 is pivotally set around the motor shaft 21 of the stator 20, provided with an upper shell 31, a lower shell 32, an intermediate shell 33 and a preset number of induction magnets 34 that are installed on the inner wall of the intermediate shell 33, corresponding to the circumference of the stator 20.

The detecting device 40 is fixed on a top surface of the silica steel plates 22 of the stator 20, including three detecting elements 41 that are composed of Hall elements. It is to be noted that the upper end of the induction magnets 34 to be induced with the detecting elements 41 is extended upwards with a preset length to form a detecting zone (H) located at a level at least 2 mm higher than that of a detectable range (S), enabling the induction magnets 34 to surely induce with the detecting elements 41 of the detecting device 40.

The circuit board 50 is fixed above and connected with the detecting device 40.

In assembly, as shown in FIGS. 5˜8, if one of the silica steel plates 22 is assembled bias at the circumference of the motor shaft 21, the stator 20 is to be positioned obliquely as the conventional one does. But, unlike the conventional one, the induction magnets 34 are still able to induce completely with the detecting device 40 installed on the stator 20 owing to the detecting zone (H) located on the upper end of the induction magnets 34, at least 2 mm higher than the detectable range (S) covered by the detecting elements 41 of the detecting device 40. Therefore, the signals of the changes of the magnetic field of the induction magnets 34 can be steadily detected by the detecting device 40 to transmit to the circuit board 50 so as to induce the magnet coils 221 of the stator 20, activating the rotor 30 to steadily whirl in a same direction without shaking.

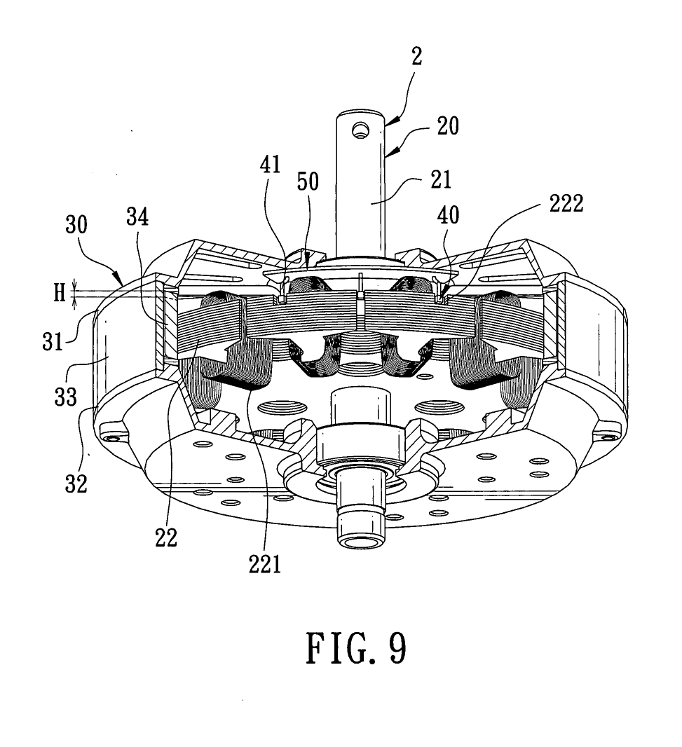

As shown in FIG. 9, a second preferred embodiment of a detecting device for a motor 2 of a ceiling fan in the present invention has the same components as the first embodiment does, except that there are three recesses 222 provided in the top surface of the silica steel plates 22 for fitting therein the detecting elements 41 of the detecting device 40. In order to keep two—one high and one low—ends of the detecting device 40 located in a level lower than that of the detecting zone (H) covered by the induction magnet 34 and enable the detecting device 40 to mutually induce with the induction magnets 34 without any error. Further, the supporting recesses 222 can be coated with adhesive to bind the detecting elements 41 more tightly therein.

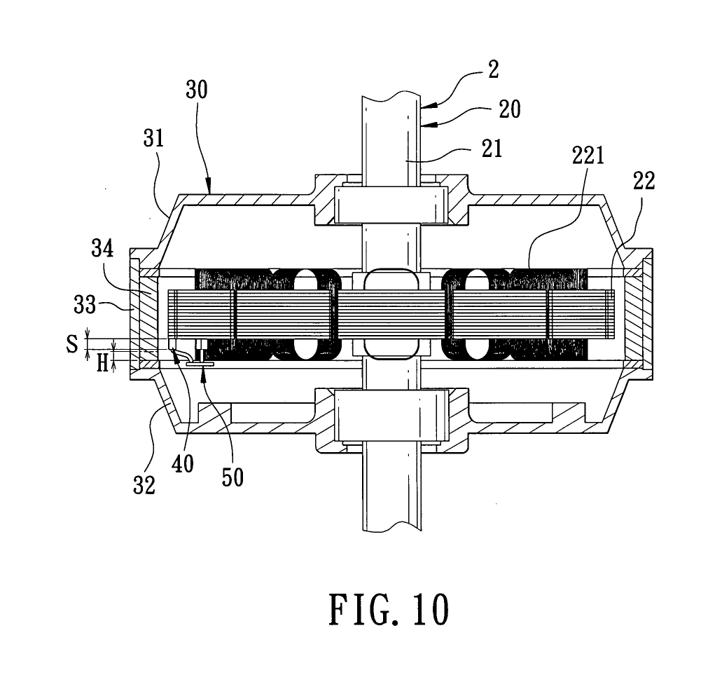

Next, as shown in FIG. 10, a third preferred embodiment of a detecting device for a motor 2 of a ceiling fan in the present invention has the same components as the first embodiment does, except that the detecting device 40 is fixed at a preset location on a bottom surface of the silica steel plates 22 of the stator 20. The lower end of each of the induction magnets 34 is extended downwards with a preset length to form a detecting zone (H) located at a level at least 2 mm lower than that of the detectable range (S). Therefore, when the induction magnets 34 are turned around together with the rotors 30, they can be surely induced with the detecting device 40 completely without any error because the lower end of the induction magnets 34 are leveled lower than that of the detecting device 40 to form the reliable detecting zone (H).

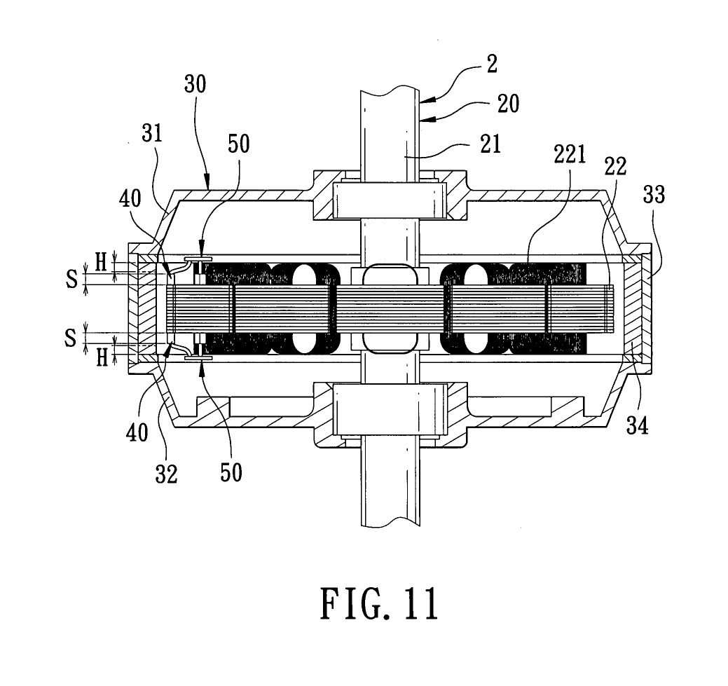

As shown in FIG. 11, a fourth preferred embodiment of a detecting device for a motor 2 of a ceiling fan in the present invention has the same components as the first embodiment does, except that two (one high and one low) ends of the induction magnets 34 are respectively extended outwards with a preset length to form a detecting zone (H) located at a level at least 2 mm higher or lower than that of the detectable range (S). Therefore, like the first and the third embodiment, when the induction magnets 34 are turned around with the rotor 30, they can be surely induced with the detecting device 40 without any error.

The advantages of the invention are described below as can be seen from the foresaid description. Even if one of the silica steel plates 22 should be assembled bias to keep the stator 20 positioned obliquely, the detecting device 40 could still induce with the induction magnets 34 completely as at least one end of the induction magnets 34 is extended with a preset length to form a detecting zone (H), keeping the rotor 30 able to rotate steadily without shaking.

While the preferred embodiment of the invention has been described above, it will be recognized and understood that various modifications may be made therein and the appended claims are intended to cover all such modifications that may fall within the spirit and scope of the invention.

What is claimed is:

1. A detecting device for a motor of a ceiling fan, said motor at least comprising:
a stator composed of a motor shaft and a preset number of laminated silica steel plates wound with plural magnet coils;
a rotor pivotally set around said motor shaft of said stator and provided with an upper shell, a lower shell, an intermediate shell, and a preset number of induction magnets that are fixed on an inner wall of said intermediate shell to correspond to a circumference of said stator;
a detecting device fixed on a surface of said laminated silica-steel-plates and connected with a circuit board to transmit signals of the changes of the magnetic field detected from said induction magnet to said circuit board; and
said motor characterized by that the end of said induction magnets to be induced with said detecting device is extended with a preset length able to cover at least a detectable range of said detecting device so as to form a reliable detecting zone between said induction magnets and said detecting device.

2. The detecting device for a motor of a ceiling fan as claimed in claim 1, wherein said preset length of said induction magnets is at least 2 mm longer than the detectable range of said detecting device.

3. The detecting device for a motor of a ceiling fan as claimed in claim 1, wherein said detecting device is set at a preset location on an upper surface of said silica steel plates and each of said induction magnets is extended upwards from its top with said preset length having a level higher than that of said detectable range of said detecting device, so as to form said reliable detecting zone.

4. The detecting device for a motor of a ceiling fan as claimed in claim 1, wherein said detecting device is set at a preset location on a lower surface of said silica steel plates and each of said induction magnets is extended downwards from its bottom with said preset length having a level lower than that of said detectable range of said detecting device, so as to form said reliable detecting zone.

5. The detecting device for a motor of a ceiling fan as claimed in claim 1, wherein two—one high and one low—ends of said induction magnets are respectively extended with said preset length to form said reliable detecting zone.

6. The detecting device for a motor of a ceiling fan as claimed in claim 1, wherein said detecting device is composed of a preset number of detecting elements.

7. The detecting device for a motor of a ceiling fan as claimed in claim 6, wherein said detecting elements are Hall elements.

8. The detecting device for a motor of a ceiling fan as claimed in claim 6, wherein said detecting device is composed of three of said detecting elements.

9. The detecting device for a motor of a ceiling fan as claimed in claim 8, wherein said detecting elements are Hall elements.

10. The detecting device for a motor of a ceiling fan as claimed in claim 1, wherein the top edge of said silica steel plates is cut with plural supporting recesses at preset locations for fitting said detecting device therein

11. The detecting device for a motor of a ceiling fan as claimed in claim 10, wherein said supporting recesses are coated with adhesive after fitted with said detecting elements, so as to keep said detecting elements stuck more tightly therein.
